(19) United States
(12) Patent Application Publication
(10) Pub. No.: US 2025/0070750 A1
(43) Pub. Date: Feb. 27, 2025

(54) ACOUSTIC WAVE DEVICE AND FILTER APPARATUS

(71) Applicant: Murata Manufacturing Co., Ltd., Nagaokakyo-shi (JP)

(72) Inventors: Sho NAGATOMO, Nagaokakyo-shi (JP); Junji YAMAUCHI, Nagaokakyo-shi (JP)

(21) Appl. No.: 18/943,048

(22) Filed: Nov. 11, 2024

Related U.S. Application Data
(63) Continuation of application No. PCT/JP2023/017987, filed on May 12, 2023.
(60) Provisional application No. 63/341,720, filed on May 13, 2022.

(51) Int. Cl. H03H 9/13; H03H 9/02; H03H 9/17; H03H 9/56

(52) U.S. Cl. CPC H03H 9/132; H03H 9/02031; H03H 9/02157; H03H 9/02228; H03H 9/173; H03H 9/176; H03H 9/562; H03H 9/564; H03H 9/568

(57) ABSTRACT

An acoustic wave device includes a support including a space in a surface thereof, a piezoelectric layer on the surface of the support, and a functional electrode on at least one surface of the piezoelectric layer to at least partially overlap the space as viewed in a first direction. The functional electrode is an interdigital transducer electrode including first and second busbars, and first and second electrode fingers. At least one electrode finger of the first and second electrode fingers includes a portion with a width that linearly changes in a second direction. In the at least one electrode finger, when a ratio of a width at a proximal end to a minimum width between the proximal end and a distal end is 1+σ:1−σ, σ is greater than or equal to about 0.01 and less than or equal to about 0.054.

### CROSS REFERENCE TO RELATED APPLICATIONS

This application claims the benefit of priority to Provisional Application No. 63/341,720 filed on May 13, 2022 and is a Continuation Application of PCT Application No. PCT/JP2023/017987 filed on May 12, 2023. The entire contents of each application are hereby incorporated herein by reference.

### BACKGROUND OF THE INVENTION

### 1. Field of the Invention

The present disclosure relates to acoustic wave devices and filter apparatuses.

### 2. Description of the Related Art

An acoustic wave device is described in Japanese Unexamined Patent Application Publication No. 2012-257019.

The acoustic wave device described in Japanese Unexamined Patent Application Publication No. 2012-257019 includes an interdigital transducer electrode. This may cause generation of f unwanted waves and lead to degradation of frequency characteristics.

### SUMMARY OF THE INVENTION

Example embodiments of the present invention reduce or prevent generation of unwanted waves.

An acoustic wave device according to an example embodiment of the present invention includes a support including a space in one principal surface thereof, a piezoelectric layer on the one principal surface of the support, and a functional electrode on at least one principal surface of the piezoelectric layer to at least partially overlap the space as viewed in a first direction which is a lamination direction of the support and the piezoelectric layer. The functional electrode is an interdigital transducer electrode including a first busbar, a second busbar facing the first busbar in a second direction crossing the first direction, a plurality of first electrode fingers including proximal ends connected to the first busbar and distal ends disposed in the second direction of the first busbar, and a plurality of second electrode fingers including proximal ends connected to the second busbar and distal ends disposed in the second direction of the second busbar. At least one electrode finger of the plurality of first electrode fingers and the plurality of second electrode fingers includes a portion with a width that linearly changes in the second direction. When a ratio of a width at the proximal end of the at least one electrode finger to a minimum width between the proximal end of the at least one electrode finger and the distal end of the at least one electrode finger is about 1+σ:1−σ, σ of the at least one electrode finger is greater than or equal to about 0.01 and less than or equal to about 0.054.

A filter apparatus according to an example embodiment of the present invention includes a plurality of resonators. At least one resonator of the plurality of resonators is defined by an acoustic wave device according to an example embodiment of the present invention.

Example embodiments of the present invention each reduce or prevent generation of unwanted waves.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a perspective view of an acoustic wave device according to a first example embodiment of the present invention.

FIG. 1B is a plan view of an electrode structure according to the first example embodiment of the present invention.

FIG. 2 is a cross-sectional view taken along line II-II of FIG. 1A.

FIG. 3A is a schematic cross-sectional view for explaining Lamb waves propagating in a piezoelectric layer of a Comparative Example.

FIG. 3B is a schematic cross-sectional view for explaining first-order thickness shear mode bulk waves propagating in a piezoelectric layer of the first example embodiment of the present invention.

FIG. 4 is a schematic cross-sectional view for explaining an amplitude direction of first-order thickness shear mode bulk waves propagating in the piezoelectric layer of the first example embodiment of the present invention.

FIG. 5 is an explanatory diagram illustrating an example of resonance characteristics of the acoustic wave device according to the first example embodiment of the present invention.

FIG. 6 is an explanatory diagram illustrating a relationship between d/2p and a fractional bandwidth of the acoustic wave device of the first example embodiment of the present invention defining and functioning as a resonator, where p is a center-to-center distance or average center-to-center distance between adjacent electrodes and d is an average thickness of the piezoelectric layer.

FIG. 7 is a schematic plan view illustrating an example of one electrode pair in an acoustic wave device according to the first example embodiment of the present invention.

FIG. 8 is a reference diagram illustrating an example of resonance characteristics of the acoustic wave device according to the first example embodiment of the present invention.

FIG. 9 is an explanatory diagram illustrating a relationship between the fractional bandwidth of the acoustic wave device of the first example embodiment of the present invention defining each of many acoustic wave resonators, and the amount of phase rotation of impedance of spurious radiation normalized at about 180 degrees as the magnitude of spurious radiation.

FIG. 10 is an explanatory diagram illustrating a relationship between d/2p, a metallization ratio MR, and a fractional bandwidth.

FIG. 11 is an explanatory diagram illustrating a map of fractional bandwidth with respect to Euler angles (0°, θ, ψ) of LiNbO₃ obtained when d/p is brought as close as possible to 0.

FIG. 12 is a partial cutaway perspective view for explaining an acoustic wave device according to an example embodiment of the present invention.

FIG. 13 is a schematic plan view illustrating an example of an electrode structure of an acoustic wave device according to the first example embodiment of the present invention.

FIG. 14 is a diagram illustrating impedance characteristics of the acoustic wave device according to the first example embodiment of the present invention.

FIG. 15 is a diagram illustrating a strength index of unwanted waves with respect to the value of σ of the acoustic wave device according to the first example embodiment of the present invention.

FIG. 16 is a diagram illustrating the value of figure of merit (FoM) with respect to the value of σ of the acoustic wave device according to the first example embodiment of the present invention.

FIG. 17 is a diagram illustrating admittance characteristics of the acoustic wave device according to the first example embodiment of the present invention.

FIG. 18 is a schematic plan view illustrating an example of an electrode structure of an acoustic wave device according to a second example embodiment of the present invention.

FIG. 19 is a schematic plan view illustrating an example of an electrode structure of an acoustic wave device according to a third example embodiment of the present invention.

FIG. 20 is a circuit diagram illustrating an example of a filter apparatus according to a fourth example embodiment of the present invention.

### DETAILED DESCRIPTION OF THE EXAMPLE EMBODIMENTS

Example embodiments of the present invention will now be described in detail with reference to the drawings. The example embodiments described below do not limit the present invention. The example embodiments of the present invention are presented for illustrative purposes. In modifications and second and other example embodiments that follow where some components of different example embodiments can be replaced or combined, the description of matters common to the first example embodiment will be omitted and only differences will be described. In particular, the same or substantially the same operations and advantageous effects achieved by the same or corresponding configurations will not be described for every example embodiment.

### First Example Embodiment

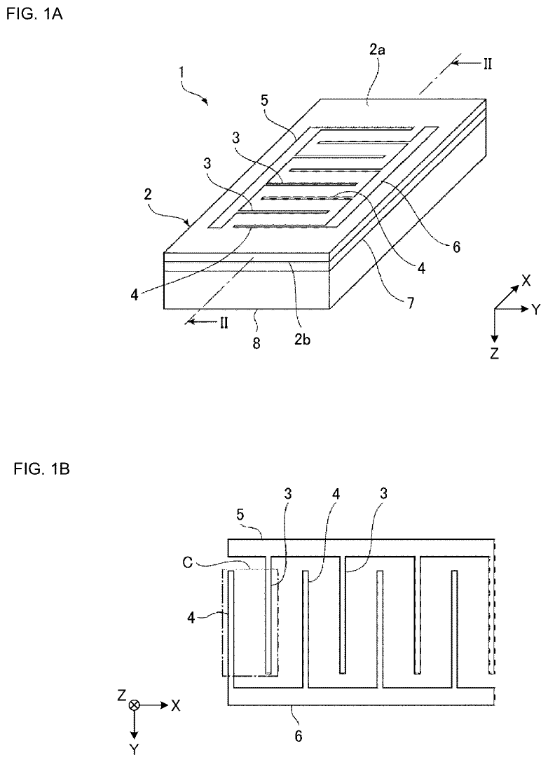

FIG. 1A is a perspective view of an acoustic wave device according to a first example embodiment of the present invention. FIG. 1B is a plan view of an electrode structure according to the first example embodiment.

An acoustic wave device 1 according to the first example embodiment includes a piezoelectric layer 2 made of, for example, LiNbO₃. The piezoelectric layer 2 may be made of, for example, LiTaO₃. The cut-angles of LiNbO₃ and LiTaO₃ are Z-cut in the first example embodiment. The cut-angles of LiNbO₃ and LiTaO₃ may be rotated Y-cut or X-cut. It is preferable that the propagation orientation is Y-propagation and X-propagation±about 30°, for example.

The thickness of the piezoelectric layer 2 is not particularly limited. For effective excitation of first-order thickness shear mode, the thickness of the piezoelectric layer 2 is, for example, preferably greater than or equal to about 50 nm and less than or equal to about 1000 nm.

The piezoelectric layer 2 includes a first principal surface 2a and a second principal surface 2b opposite each other in the Z direction. Electrode fingers 3 and 4 are arranged on the first principal surface 2a.

Here, the electrode finger 3 is an example of “first electrode finger”, and the electrode finger 4 is an example of “second electrode finger”. In FIG. 1A and FIG. 1B, a plurality of electrode fingers 3 are a plurality of “first electrode fingers” connected to a first busbar 5, and a plurality of electrode fingers 4 are a plurality of “second electrode fingers” connected to a second busbar 6. The plurality of electrode fingers 3 and the plurality of electrode fingers 4 are interdigitated with each other. The electrode fingers 3, the electrode fingers 4, the first busbar 5, and the second busbar 6 thus define an interdigital transducer (IDT) electrode.

The electrode fingers 3 and 4 are rectangular or substantially rectangular in shape and have a length direction. In a direction orthogonal or substantially orthogonal to the length direction, adjacent ones of the electrode fingers 3 and 4 face each other. The length direction of the electrode fingers 3 and 4 and the direction orthogonal or substantially orthogonal to the length direction of the electrode fingers 3 and 4 are directions that cross the thickness direction of the piezoelectric layer 2. Therefore, adjacent ones of the electrode fingers 3 and 4 can also be considered facing each other in the direction crossing the thickness direction of the piezoelectric layer 2. Hereinafter, the thickness direction of the piezoelectric layer 2 may be described as a Z direction (or first direction), the length direction of the electrode fingers 3 and 4 may be described as a Y direction (or second direction), and the direction orthogonal or substantially orthogonal to the electrode fingers 3 and 4 may be described as an X direction (or third direction).

The length direction of the electrode fingers 3 and 4 may be interchanged with the direction orthogonal or substantially orthogonal to the length direction of the electrode fingers 3 and 4 illustrated in FIG. 1A and FIG. 1B. That is, the electrode fingers 3 and 4 may extend in the direction in which the first busbar 5 and the second busbar 6 extend in FIG. 1A and FIG. 1B. In this case, the first busbar 5 and the second busbar 6 extend in the direction in which the electrode fingers 3 and 4 extend in FIG. 1A and FIG. 1B. A plurality of pairs of adjacent electrode fingers 3 and 4, the electrode finger 3 being connected to one potential and the electrode finger 4 being connected to the other potential, are arranged in the direction orthogonal or substantially orthogonal to the length direction of the electrode fingers 3 and 4.

Here, the electrode fingers 3 and 4 adjacent to each other are not in direct contact, but are spaced apart from each other. The electrode fingers 3 and 4 adjacent to each other are not provided with other electrodes (including other electrode fingers 3 and 4) connected to hot and ground electrodes therebetween. The number of pairs of adjacent electrode fingers 3 and 4 does not necessarily need to be an integer, and there may be, for example, 1.5 pairs or 2.5 pairs.

A center-to-center distance, or pitch, between the electrode fingers 3 and 4 is, for example, preferably greater than or equal to about 1 μm and less than or equal to about 10 μm. The center-to-center distance between the electrode fingers 3 and 4 is a distance from the center of the width dimension of the electrode finger 3 in the direction orthogonal or substantially orthogonal to the length direction of the electrode finger 3 to the center of the width dimension of the electrode finger 4 in the direction orthogonal or substantially orthogonal to the length direction of the electrode finger 4.

When the number of at least one of the electrode fingers 3 and 4 is more than one (i.e., there are greater than or equal to 1.5 electrode pairs, each including the electrode finger 3 and the electrode finger 4), the center-to-center distance between the electrode fingers 3 and 4 is the average of the center-to-center distances between adjacent ones of the greater than or equal to 1.5 pairs of electrode fingers 3 and 4.

The width of the electrode fingers 3 and 4, or the dimension of the electrode fingers 3 and 4 in the direction in which the electrode fingers 3 and 4 face each other, is, for example, preferably greater than or equal to about 150 nm and less than or equal to about 1000 nm. The center-to-center distance between the electrode fingers 3 and 4 is a distance from the center of the dimension (width dimension) of the electrode finger 3 in the direction orthogonal or substantially orthogonal to the length direction of the electrode finger 3 to the center of the dimension (width dimension) of the electrode finger 4 in the direction orthogonal to the length direction of the electrode finger 4.

In the first example embodiment, where a Z-cut piezoelectric layer is used, the direction orthogonal or substantially orthogonal to the length direction of the electrode fingers 3 and 4 is a direction orthogonal or substantially orthogonal to the polarization direction of the piezoelectric layer 2. This is not applicable when a piezoelectric body with other cut-angles is used as the piezoelectric layer 2. Here, the term “orthogonal” may refer not only to being exactly orthogonal, but also to being substantially orthogonal (e.g., the angle between the direction orthogonal to the length direction of the electrode fingers 3 and 4 and the polarization direction is about 90°+) 10°.

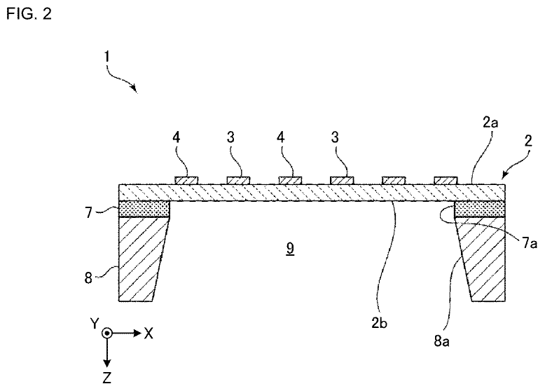

A support substrate 8 is disposed adjacent to the second principal surface 2b of the piezoelectric layer 2, with an intermediate layer 7 interposed therebetween. The support substrate 8 and the intermediate layer 7 define a support. The intermediate layer 7 and the support substrate 8 have a frame shape. As illustrated in FIG. 2, the intermediate layer 7 and the support substrate 8 are provided with cavities 7a and 8a, respectively, which define a space (air gap) 9. The space may be provided only in the intermediate layer 7. That is, the intermediate layer 7 may include a recess. In this case, the recess defines the space.

The space 9 is provided to allow vibration of an excitation region C of the piezoelectric layer 2. Therefore, the support substrate 8 is disposed adjacent to the second principal surface 2b, with the intermediate layer 7 interposed therebetween, so as not to overlap at least one pair of electrode fingers 3 and 4. The intermediate layer 7 is optional. That is, the support substrate 8 may be disposed on the second principal surface 2b of the piezoelectric layer 2, either directly or indirectly.

The intermediate layer 7 is made of, for example, silicon oxide. The intermediate layer 7 can be made of an appropriate insulating material, such as, for example, silicon nitride or alumina, other than silicon oxide.

The support substrate 8 is made of, for example, Si. The plane orientation of the Si substrate on the surface thereof adjacent to the piezoelectric layer 2 may be (100), (110), or (111). It is preferable that the Si is a high-resistance Si with a resistivity of, for example, greater than or equal to about 4 kΩ. The support substrate 8 can also be made of an appropriate insulating material or semiconductor material. Examples of the material used for the support substrate 8 include piezoelectric materials, such as aluminum oxide, lithium tantalate, lithium niobate, and crystals; various ceramics, such as alumina, magnesia, sapphire, silicon nitride, aluminum nitride, silicon carbide, zirconia, cordierite, mullite, steatite, and forsterite; dielectrics, such as diamond and glass; and a semiconductor, such as gallium nitride.

The plurality of electrode fingers 3 and 4, the first busbar 5, and the second busbar 6 are made of an appropriate metal, for example, such as Al, or an appropriate alloy, such as AlCu alloy. In the first example embodiment, the electrode fingers 3 and 4, the first busbar 5, and the second busbar 6 have a multilayer structure including, for example, a Ti film and an Al film on the Ti film. The Ti film may be replaced by a different adhesion layer.

For driving, an alternating-current voltage is applied between the plurality of electrode fingers 3 and the plurality of electrode fingers 4. Specifically, an alternating-current voltage is applied between the first busbar 5 and the second busbar 6. This can produce resonance characteristics using first-order thickness shear mode bulk waves excited in the piezoelectric layer 2.

In the acoustic wave device 1, d/p is, for example, less than or equal to 0.5, where d is the thickness of the piezoelectric layer 2 and p is the center-to-center distance between any adjacent electrode fingers 3 and 4 of the plurality of pairs of electrode fingers 3 and 4. This allows effective excitation of the first-order thickness shear mode bulk waves and can produce good resonance characteristics. It is more preferable that, d/p be less than or equal to 0.24. This produces better resonance characteristics.

As in the first example embodiment, where the number of at least one of the electrode fingers 3 and 4 is more than one (i.e., there are greater than or equal to 1.5 electrode pairs, each consisting of the electrode finger 3 and the electrode finger 4), the center-to-center distance p between the adjacent electrode fingers 3 and 4 is the average center-to-center distance between all adjacent electrode fingers 3 and 4.

In the acoustic wave device 1 of the first example embodiment configured as described above, the Q factor does not decrease easily even when the number of pairs of the electrode fingers 3 and 4 is reduced for the purpose of size reduction. This is because resonators that do not require reflectors on both sides have less propagation loss. The reflectors are not required because of the use of first-order thickness shear mode bulk waves.

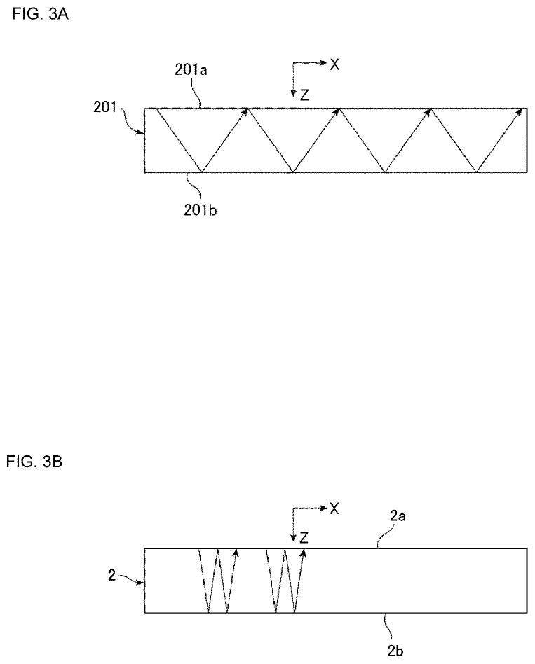

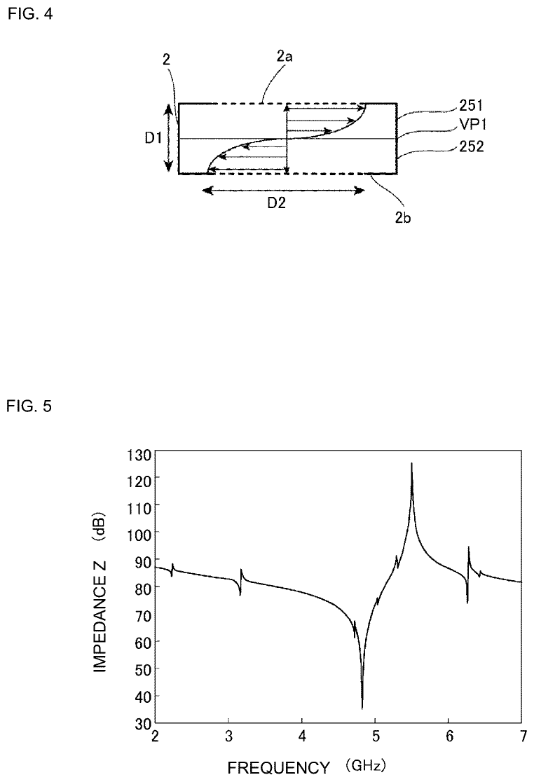

FIG. 3A is a schematic cross-sectional view for explaining Lamb waves propagating in a piezoelectric layer of a Comparative Example. FIG. 3B is a schematic cross-sectional view for explaining first-order thickness shear mode bulk waves propagating in the piezoelectric layer of the first example embodiment. FIG. 4 is a schematic cross-sectional view for explaining an amplitude direction of first-order thickness shear mode bulk waves propagating in the piezoelectric layer of the first example embodiment.

FIG. 3A illustrates Lamb waves propagating in a piezoelectric layer of an acoustic wave device, such as that described in Japanese Unexamined Patent Application Publication No. 2012-257019. As illustrated in FIG. 3A, the waves propagate in a piezoelectric layer 201 as indicated by arrows. The piezoelectric layer 201 includes a first principal surface 201a and a second principal surface 201b. A thickness direction, which connects the first principal surface 201a and the second principal surface 201b, is the Z direction. The X direction is a direction in which the electrode fingers 3 and 4 of the interdigital transducer electrode are arranged. The Lamb waves propagate in the X direction, as illustrated in FIG. 3A. Although the entire piezoelectric layer 201 vibrates, the Lamb waves (plate waves) propagate in the X direction. Reflectors are thus provided on both sides to produce resonance characteristics. This causes wave propagation loss and when the number of pairs of the electrode fingers 3 and 4 is reduced for size reduction, the Q factor decreases.

In the acoustic wave device of the first example embodiment, as illustrated in FIG. 3B, vibration displacement takes place in the thickness shear direction. Therefore, the waves propagate substantially in the direction connecting the first principal surface 2a and the second principal surface 2b of the piezoelectric layer 2, that is, substantially in the Z direction and resonate. In other words, the X direction component of the waves is much smaller than the Z direction component of the waves. Since the wave propagation in the Z direction produces resonance characteristics, the acoustic wave device requires no reflectors. This prevents propagation loss that occurs during propagation to reflectors. Therefore, the Q factor does not decrease easily even when the number of electrode pairs, each including the electrode fingers 3 and 4, is reduced for the purpose of size reduction.

As illustrated in FIG. 4, the amplitude direction of first-order thickness shear mode bulk waves in a first region 251 included in the excitation region C (see FIG. 1B) of the piezoelectric layer 2 is opposite that in a second region 252 included in the excitation region C. FIG. 4 schematically illustrates how bulk waves behave when a voltage that makes the potential of the electrode finger 4 higher than that of the electrode finger 3 is applied between the electrode fingers 3 and 4. In the excitation region C, the first region 251 is a region between a virtual plane VP1 and the first principal surface 2a, and the second region 252 is a region between the virtual plane VP1 and the second principal surface 2b. The virtual plane VP1 is orthogonal or substantially orthogonal to the thickness direction of the piezoelectric layer 2 and divides the piezoelectric layer 2 into two.

The acoustic wave device 1 includes at least one electrode pair including the electrode fingers 3 and 4. Since the acoustic wave device 1 is not configured to propagate waves in the X direction, it is not necessarily required that there be more than one electrode pair including the electrode fingers 3 and 4. That is, the acoustic wave device 1 simply requires at least one electrode pair.

For example, the electrode finger 3 is an electrode connected to the hot potential, and the electrode finger 4 is an electrode connected to the ground potential. Alternatively, the electrode finger 3 and the electrode finger 4 may be connected to the ground potential and the hot potential, respectively. In the first example embodiment, the at least one electrode pair is a combination of electrodes, one connected to the hot potential and the other connected to the ground potential, as described above, and no floating electrode is provided.

FIG. 5 is an explanatory diagram illustrating an example of resonance characteristics of the acoustic wave device according to the first example embodiment. The design parameters of the acoustic wave device 1 having the resonance characteristics illustrated in FIG. 5 are as follows.
Piezoelectric layer 2: LiNbO₃ with Euler angles (0°, 0°, 90°)
Thickness of piezoelectric layer 2: about 400 nm
Length of excitation region C (see FIG. 1B): about 40 μm
Number of electrode pairs, each consisting of electrode fingers 3 and 4: 21 pairs
Center-to-center distance (pitch) between electrode fingers 3 and 4: about 3 μm
Width of electrode fingers 3 and 4: about 500 nm d/p: about 0.133
Intermediate layer 7: about 1 μm-thick silicon oxide film
Support substrate 8: Si

The excitation region C (see FIG. 1B) is a region where the electrode fingers 3 and 4 overlap, as viewed in the X direction orthogonal or substantially orthogonal to the length direction of the electrode fingers 3 and 4. The length of the excitation region C is a dimension of the excitation region C along the length direction of the electrode fingers 3 and 4. The excitation region C is an example of “overlap region”.

In the first example embodiment, all electrode pairs, each including the electrode fingers 3 and 4, have the same or substantially the same center-to-center distance. That is, the electrode fingers 3 and 4 are arranged with an equal or substantially equal pitch.

As apparent from FIG. 5, good resonance characteristics with a fractional bandwidth of, for example, about 12.5% are obtained without reflectors.

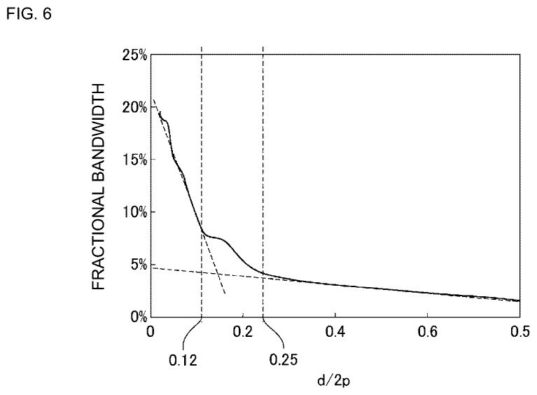

In the first example embodiment, d/p is, for example, less than or equal to about 0.5 and more preferably less than or equal to about 0.24, where d is the thickness of the piezoelectric layer 2 and p is the electrode center-to-center distance between the electrode fingers 3 and 4. This will now be described with reference to FIG. 6.

A plurality of acoustic wave devices are produced by varying d/2p of the acoustic wave device having the resonance characteristics illustrated in FIG. 5. FIG. 6 is an explanatory diagram illustrating a relationship between d/2p and a fractional bandwidth of the acoustic wave device of the first example embodiment defining and functioning as a resonator, where p is the center-to-center distance between adjacent electrodes or the average center-to-center distance between adjacent electrodes, and d is the average thickness of the piezoelectric layer 2.

As illustrated in FIG. 6, if d/2p exceeds about 0.25 (or d/p>about 0.5), the fractional bandwidth falls below about 5% even when d/p is adjusted. On the other hand, if d/2p≤about 0.25 (or d/p≤about 0.5) is satisfied, the fractional bandwidth can be made greater than or equal to about 5% by varying d/p within the range, that is, a resonator having a high coupling coefficient can be obtained. If d/2p is less than or equal to about 0.12, that is, if d/p is less than or equal to about 0.24, the fractional bandwidth can be made as high as about 7% or more. Additionally, by adjusting d/p within this range, a resonator with a wider fractional bandwidth and a higher coupling coefficient can be produced. Thus, for example, by making d/p less than or equal to about 0.5, a resonator with a higher coupling coefficient using first-order thickness shear mode bulk waves can be obtained.

Note that the at least one electrode pair may mean one pair. In the case of one electrode pair, p is the center-to-center distance between adjacent electrode fingers 3 and 4. In the case of 1.5 electrode pairs or more, p may be the average center-to-center distance between adjacent electrode fingers 3 and 4.

If the piezoelectric layer 2 varies in thickness, the average thickness of the piezoelectric layer 2 may be used as the thickness d of the piezoelectric layer 2.

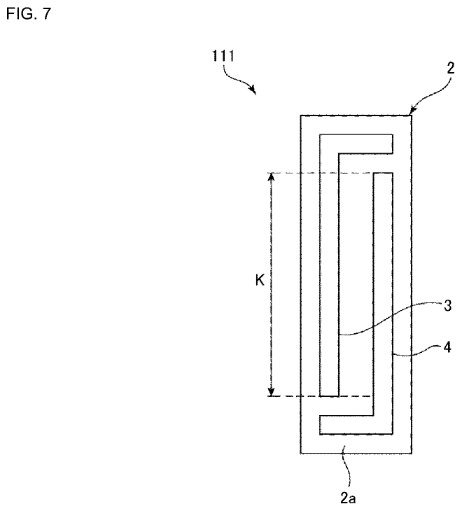

FIG. 7 is a schematic plan view illustrating an example of one electrode pair in an acoustic wave device according to the first example embodiment. An acoustic wave device 101 includes one electrode pair including the electrode fingers 3 and 4 on the first principal surface 2a of the piezoelectric layer 2. K in FIG. 7 indicates an overlap width. As described above, the acoustic wave device according to example embodiments of the present invention may include only one electrode pair. Even in this case, the first-order thickness shear mode bulk waves can be effectively excited as long as d/p is, for example, less than or equal to about 0.5.

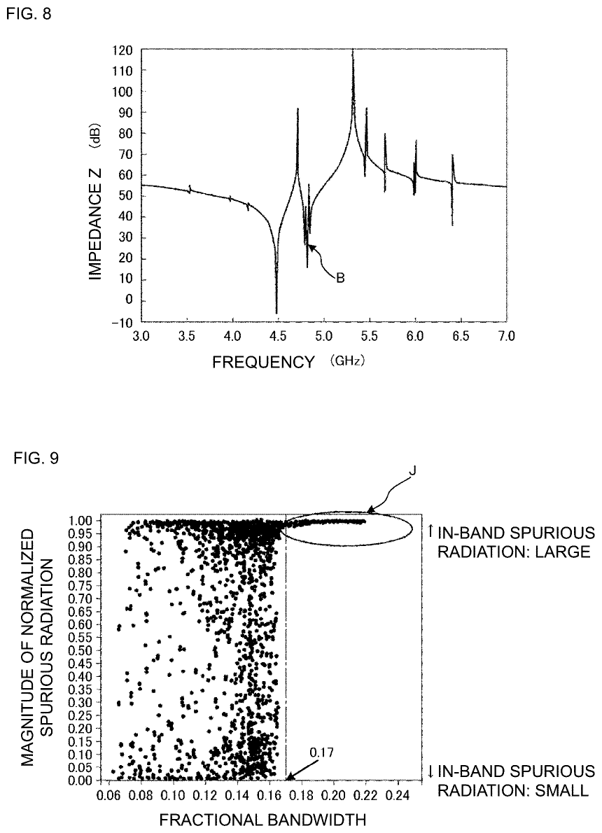

The excitation region C of the acoustic wave device 1 is a region where any adjacent electrode fingers 3 and 4 of the plurality electrode fingers 3 and 4 overlap as viewed in the direction in which the adjacent electrode fingers 3 and 4 face each other. It is preferable in the acoustic wave device 1 that, for example, MR≤about 1.75 (d/p)+0.075 be satisfied, where MR is a metallization ratio MR of the adjacent electrode fingers 3 and 4 to the excitation region C. Spurious radiation can be effectively reduced in this case. This will be described with reference to FIG. 8 and FIG. 9.

FIG. 8 is a reference diagram illustrating an example of resonance characteristics of the acoustic wave device according to the first example embodiment. Arrow B indicates a spurious radiation appearing between the resonant frequency and the anti-resonant frequency. In this example, d/p is about 0.08, LiNbO₃ has Euler angles (0°, 0°, 90°), and the metallization ratio MR is about 0.35.

The metallization ratio MR will now be described with reference to FIG. 1B. To focus on one pair of electrode fingers 3 and 4 in the electrode structure illustrated in FIG. 1B, the description assumes that only the one pair of electrode fingers 3 and 4 is provided. In this case, a region enclosed by a dash-dot line is the excitation region C. When the electrode fingers 3 and 4 are viewed in the direction orthogonal or substantially orthogonal to the length direction of the electrode fingers 3 and 4 (or viewed in the direction in which the electrode fingers 3 and 4 face each other), the excitation region C includes a portion of the electrode finger 3 overlapping the electrode finger 4, a portion of the electrode finger 4 overlapping the electrode finger 3, and a portion between the electrode fingers 3 and 4 where the electrode fingers 3 and 4 overlap. The metallization ratio MR is the ratio of the area of the electrode fingers 3 and 4 in the excitation region C to the area of the excitation region C. That is, the metallization ratio MR is the ratio of the area of a metallized portion to the area of the excitation region C.

When a plurality of pairs of electrode fingers 3 and 4 are provided, MR may be the ratio of the area of metallized portions included in all excitation regions C to the sum of the areas of the excitation regions C.

FIG. 9 is an explanatory diagram illustrating a relationship between the fractional bandwidth of the acoustic wave device of the first example embodiment defining each of many acoustic wave resonators, and the amount of phase rotation of impedance of spurious radiation normalized at about 180 degrees as the magnitude of spurious radiation. The fractional bandwidth is adjusted by varying the film thickness of the piezoelectric layer 2 or the dimensions of the electrode fingers 3 and 4. FIG. 9 illustrates a result of using, for example, a Z-cut LiNbO₃ layer as the piezoelectric layer 2. A similar tendency is observed when the piezoelectric layer 2 with other cut-angles is used.

In the region enclosed by oval J in FIG. 9, the level of spurious radiation is as high as about 1.0. As apparent from FIG. 9, when the fractional bandwidth exceeds about 0.17 or about 17%, a large spurious radiation with a spurious radiation level of about 1 or higher appears in the pass band even if parameters defining the fractional bandwidth are changed. That is, as in the resonance characteristics illustrated in FIG. 8, a large spurious radiation indicated by arrow B appears in the band. Therefore, for example, it is preferable that the fractional bandwidth be less than or equal to about 17%. In this case, adjusting the film thickness of the piezoelectric layer 2 or the dimensions of the electrode fingers 3 and 4 can reduce spurious radiation.

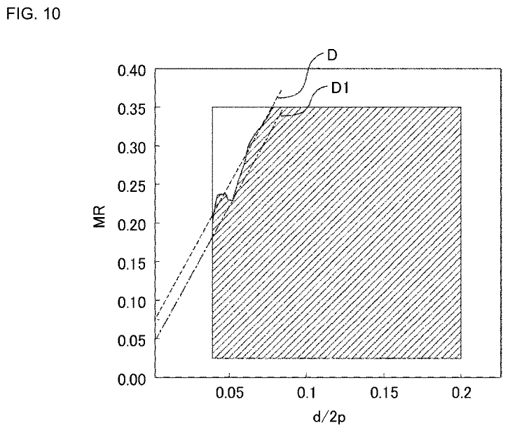

FIG. 10 is an explanatory diagram illustrating a relationship between d/2p, a metallization ratio MR, and a fractional bandwidth. Various acoustic wave devices 1 were made by varying d/2p and MR of the acoustic wave device 1 of the first example embodiment to measure the fractional bandwidths. In FIG. 10, a hatched region to the right of broken line D is a region where the fractional bandwidth is less than or equal to about 17%. The boundary between the hatched and non-hatched regions is, for example, represented by MR=about 3.5 (d/2p)+0.075 or MR=about 1.75 (d/p)+0.075, and preferably MR≤about 1.75 (d/p)+0.075. In this case, it is easier to make the fractional bandwidth less than or equal to about 17%. A more preferable region is, for example, one that is to the right of the boundary represented by MR=about 3.5 (d/2p)+0.05, indicated by dash-dot line D1 in FIG. 10. That is, for example, if MR≤about 1.75 (d/p)+0.05 is satisfied, the fractional bandwidth can be reliably made less than or equal to about 17%.

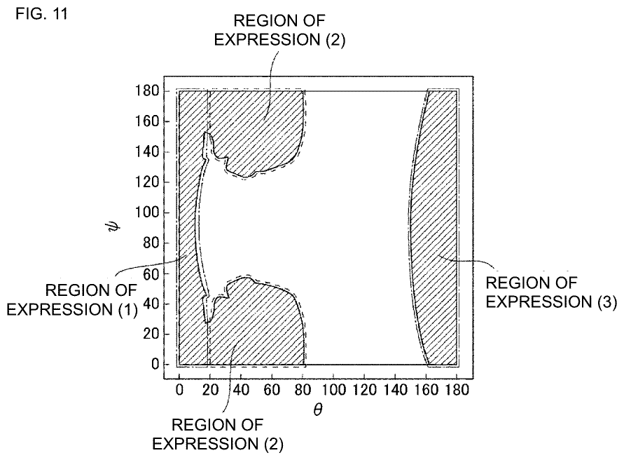

FIG. 11 is an explanatory diagram illustrating a map of fractional bandwidth with respect to Euler angles (0°, θ, ψ) of LiNbO₃ obtained when d/p is brought as close as possible to 0. Hatched regions in FIG. 11 are regions where a fractional bandwidth of at least greater than or equal to about 5% can be obtained. By approximating the ranges of these regions, ranges defined by expression (1), expression (2) and expression (3) described below are obtained.

$$( 0 ° \pm 10 ° , 0 ° to 20 ° , any ψ ) \qquad expression ( 1 )$$

$$( 0 ° \pm 10 ° , 20 ° to 80 ° , 0 ° to 60 ° {( 1 + {( θ - 50 )}^{2} / 900 )}^{1 / 2} ) or ( 0 ° \pm 10 ° , 20 ° to 80 ° , \{ 180 ° - 60 ° {( 1 - {( θ - 50 )}^{2} / 900 )}^{1 / 2} \} to 180 ° ) \qquad expression ( 2 )$$

$$( 0 ° \pm 10 ° , \{ 180 ° - 30 {° ( 1 - {( ψ - 90 )}^{2} / 8100 )}^{1 / 2} \} to 180 ° , any ψ ) \qquad expression ( 3 )$$

The ranges of the Euler angles defined by expression (1), expression (2), or expression (3) are preferable, because a sufficiently wide fractional bandwidth can be achieved.

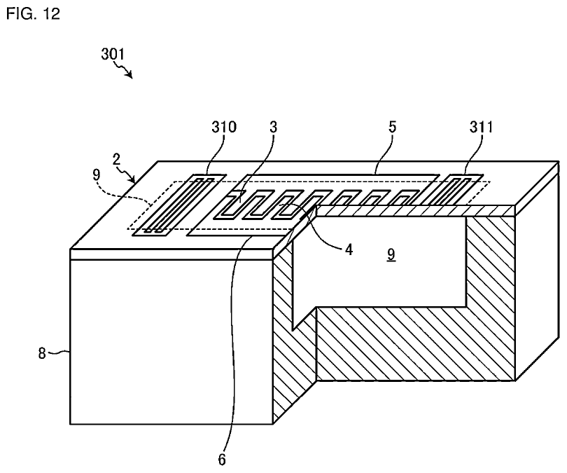

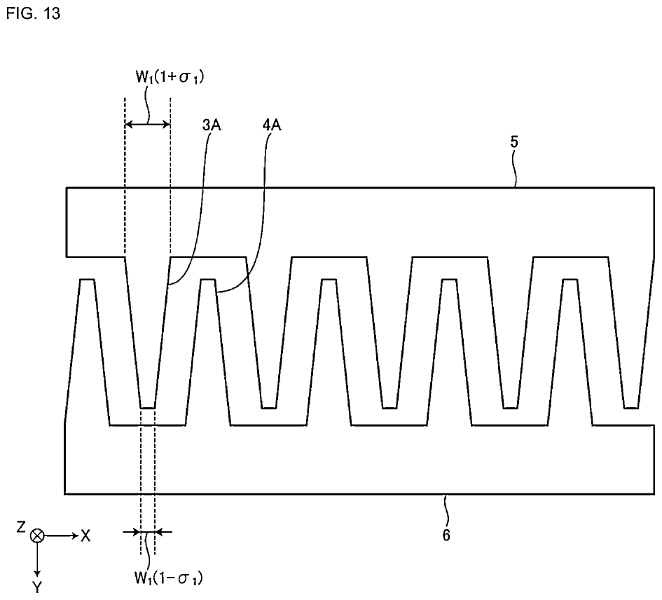

FIG. 12 is a partial cutaway perspective view for explaining an acoustic wave device according to an example embodiment of the present invention. In FIG. 12, the outer edge of the space 9 is indicated by a broken line. An acoustic wave device according to an example embodiment of the present invention may use plate waves. In this case, an acoustic wave device 301 includes reflectors 310 and 311, as illustrated in FIG. 12. The reflectors 310 and 311 are disposed on both sides of the electrode fingers 3 and 4 on the piezoelectric layer 2 in the propagation direction of acoustic waves. In the acoustic wave device 301, Lamb waves (or plate waves) are excited by applying an alternating-current electric field to the electrode fingers 3 and 4 above the space 9. With the reflectors 310 and 311 on both sides, the resonance characteristics based on Lamb waves (or plate waves) can be obtained.

As described above, the acoustic wave devices 1 and 101 use first-order thickness shear mode bulk waves. In the acoustic wave devices 1 and 101, the first and second electrode fingers 3 and 4 are adjacent electrodes and d/p is, for example, less than or equal to about 0.5, where d is the thickness of the piezoelectric layer 2 and p is the center-to-center distance between the first and second electrode fingers 3 and 4. This can improve the Q factor even when the acoustic wave device is reduced in size.

In the acoustic wave devices 1 and 101, the piezoelectric layer 2 is made of, for example, lithium niobate or lithium tantalate. The first principal surface 2a or the second principal surface 2b of the piezoelectric layer 2 includes thereon the first and second electrode fingers 3 and 4 facing each other in the direction crossing the thickness direction of the piezoelectric layer 2. The first and second electrode fingers 3 and 4 are preferably covered with a protective film.

FIG. 13 is a schematic plan view illustrating an example of an electrode structure of an acoustic wave device according to the first example embodiment. As illustrated in FIG. 13, a functional electrode of an acoustic wave device 1A according to the first example embodiment is an interdigital transducer electrode including electrode fingers 3A and 4A and the busbars 5 and 6. In the example illustrated in FIG. 13, the functional electrode is disposed on the first principal surface 2a of the piezoelectric layer 2. Of end portions of the electrode fingers 3A and 4A in the Y direction, those connected to the busbars 5 and 6 will be referred to as proximal ends, and those not connected to the busbars 5 and 6 will be referred to as distal ends in the following description.

As illustrated in FIG. 13, the electrode fingers 3A and 4A include a portion with a width that linearly changes in the Y direction. In other words, the electrode fingers 3A and 4A include a portion where a position in the Y direction and the width of the electrode fingers 3A and 4A have a linear relationship. In the first example embodiment, all of the electrode fingers 3A and 4A have a shape with a width that linearly changes in the Y direction. The electrode fingers 3A and 4A have a trapezoidal shape, for example. That is, the electrode fingers 3A and 4A have a shape with a width that linearly changes in the Y direction from the proximal end to the distal end. In the example illustrated in FIG. 13, the electrode fingers 3A and 4A are in the shape of, for example, an isosceles trapezoid with a width that decreases from the proximal end to the distal end in plan view in the Z direction. That is, the electrode fingers 3A and 4A are symmetrical or substantially symmetrical in shape in the X direction. The electrode fingers 3A and 4A have a width that is largest at the proximal end and smallest at the distal end.

In the following description, the width at the proximal end of the electrode fingers 3A and 4A is W₁ (1+σ), and the minimum width between the proximal end and the distal end of the electrode fingers 3A and 4A is W₁ (1−σ). That is, the ratio of the width at the proximal end of the electrode fingers 3A and 4A to the minimum width between the proximal end and the distal end of the electrode fingers 3A and 4A is 1+σ:1−σ. W₁ can be the average length of the width at the proximal end of the electrode fingers 3A and 4A and the width at the distal end of the electrode fingers 3A and 4A.

The value of σ is, for example, greater than or equal to about 0.001 and less than or equal to about 0.054, and is preferably greater than or equal to about 0.03. This can reduce or prevent generation of unwanted waves without degrading the figure of merit (FOM). FoM is an index indicating the performance of an oscillator, and is the product of a coupling coefficient and a Q factor.

Although an example of the acoustic wave device according to the first example embodiment has been described, the acoustic wave device according to the first example embodiment is not limited to that illustrated in FIG. 13. For example, although the electrode fingers 3A and 4A have an isosceles trapezoidal shape, the shape of the electrode fingers 3A and 4A is not limited to this. The electrode fingers 3A and 4A may be, for example, in the shape of a non-isosceles trapezoid with a width that decreases from the proximal end toward the distal end. It is simply required that at least one of electrode fingers of the interdigital transducer electrode includes a portion with a width that linearly changes in the Y direction.

Examples of the first example embodiment will now be described. The present invention is not limited to Examples described below.

### Comparative Example 1

An acoustic wave device according to Comparative Example 1 is an acoustic wave device in which σ is 0 or approximately 0. That is, the acoustic wave device according to Comparative Example 1 is an acoustic wave device where the electrode fingers 3 and 4 have a rectangular or substantially rectangular shape with a constant width.

### Example 1

An acoustic wave device according to Example 1 is an acoustic wave device in which all of the electrode fingers have an isosceles trapezoidal shape with a width that linearly decreases from the proximal end to the distal end. In Example 1, σ is about 0.05.

### Examples 2 and 3

An acoustic wave device according to Example 2 is the same or substantially the same as that according to Example 1 except that σ is about 0.01. An acoustic wave device according to Example 3 is the same or substantially the same as that according to Example 1 except that σ is about 0.03.

### Examples 4 and 5

An acoustic wave device according to Example 4 is the same or substantially the same as that according to Example 1 except that σ is about 0.027. An acoustic wave device according to Example 5 is the same or substantially the same as that according to Example 1 except that σ is about 0.054.

### Comparative Example 2

An acoustic wave device according to Comparative Example 2 is the same or substantially the same as that according to Example 1 except that σ is about 0.108.

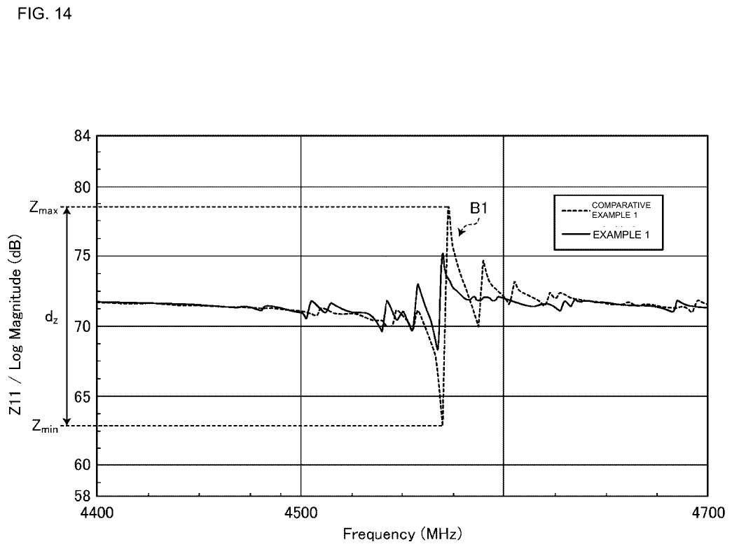

FIG. 14 is a diagram illustrating impedance characteristics of the acoustic wave device according to the first example embodiment. Specifically, FIG. 14 illustrates unwanted waves of the acoustic wave devices according to Comparative Example 1 and Example 1. As illustrated in FIG. 14, in Example 1 where the width of the electrode fingers 3A and 4A linearly changes in the Y direction, the magnitude of unwanted waves indicated by arrow B1 is more reduced or prevented than in Comparative Example 1 where the width of the electrode fingers 3A and 4A is constant in the Y direction. This indicates that with the electrode fingers 3A and 4A having a width that linearly changes in the Y direction, the generation of unwanted waves can be reduced or prevented. In the following description, a decibel difference between the minimum value Zₘᵢₙ (Ω) and the maximum value Zₘₐₓ (Ω) of impedance of unwanted waves, indicated by arrow B1, will be described as a strength index d_{z} of the unwanted waves. That is, d_{z}=log 10 (Zₘₐₓ/Zₘᵢₙ).

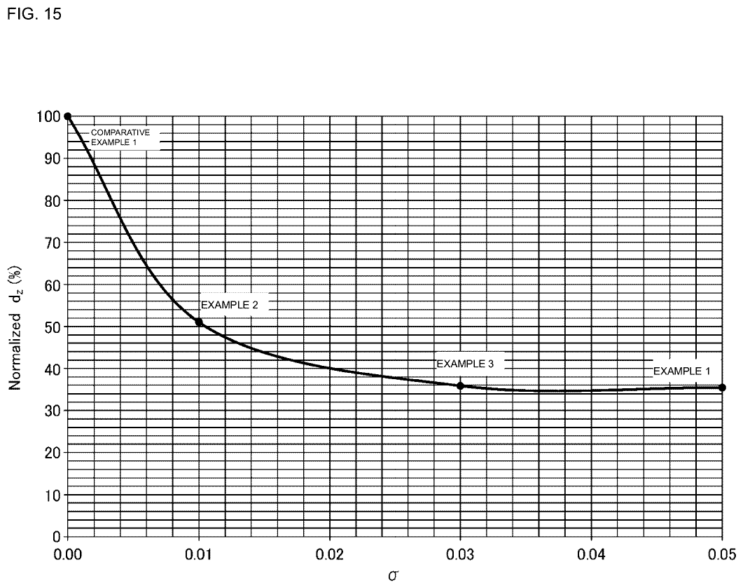

FIG. 15 is a diagram illustrating a strength index of unwanted waves with respect to the value of σ of the acoustic wave device according to the first example embodiment. Specifically, FIG. 15 is a graph illustrating a relation between σ and the value of the strength index d_{z} of unwanted waves normalized by the strength index of unwanted waves in Comparative Example 1. As illustrated in FIG. 15, in Examples 1 to 3 where σ is greater than or equal to about 0.001, the strength index d_{z} of unwanted waves is smaller than that in Comparative Example 1 where σ is 0 or approximately 0. In Examples 2 and 3 where σ is greater than or equal to about 0.03, the strength index d_{z} of unwanted waves is less than or equal to about half that in Comparative Example 1 where σ is 0 or approximately 0. This indicates that generation of unwanted waves can be reduced or prevented, for example, by making σ greater than or equal to about 0.001, and that generation of unwanted waves can be further reduced or prevented by making σ greater than or equal to about 0.03.

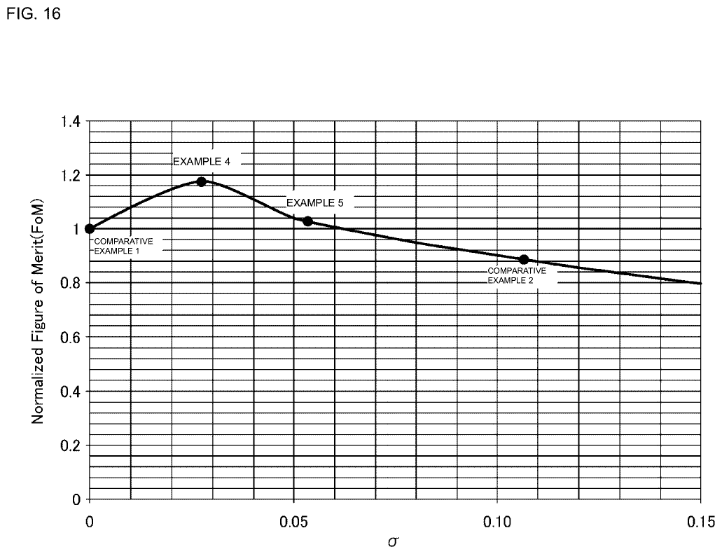

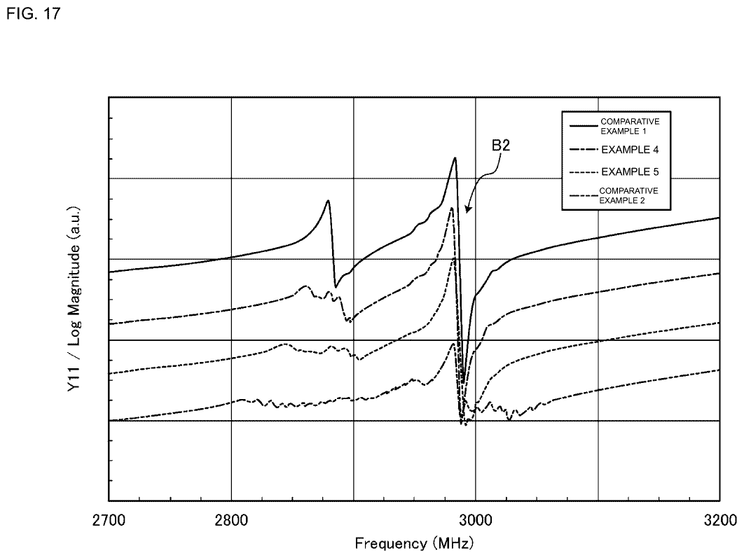

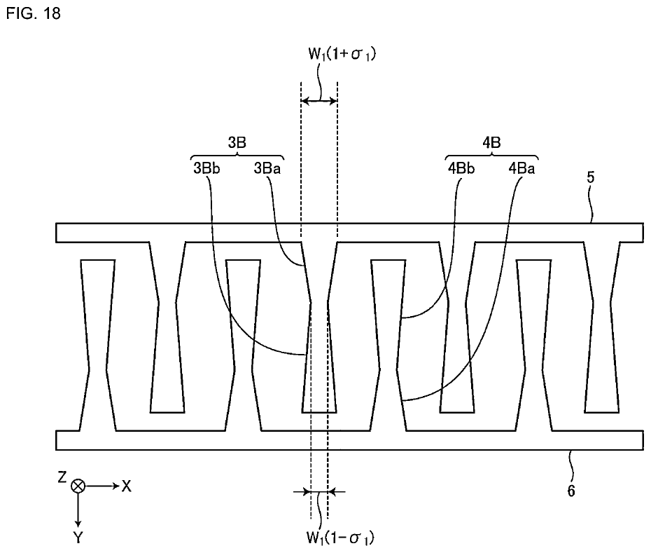

FIG. 16 is a diagram illustrating the value of figure of merit (FoM) with respect to the value of σ of the acoustic wave device according to the first example embodiment. Specifically, FIG. 16 is a graph illustrating a relationship between σ and the value of FOM normalized by the value of FOM in Comparative Example 1. FIG. 17 is a diagram illustrating admittance characteristics of the acoustic wave device according to the first example embodiment. As illustrated in FIG. 16, in Examples 4 and 5 where σ is greater than or equal to about 0.001 and less than or equal to about 0.054, FoM is greater than that in Comparative Example 1 where σ is 0 and in Comparative Example 2 where σ is greater than or equal to about 0.054. As illustrated in FIG. 17, in Examples 4 and 5 where σ is greater than or equal to about 0.001 and less than or equal to about 0.054, the generation of unwanted waves indicated by arrow B2 is more reduced or prevented than in Comparative Example 1 where σ is 0 or approximately 0. This indicates that, for example, by making σ greater than or equal to about 0.001 and less than or equal to about 0.054, it is possible to reduce or prevent generation of unwanted waves while reducing or preventing degradation of FoM.

As described above, the acoustic wave device according to the first example embodiment includes the support including the space 9 in one principal surface thereof, the piezoelectric layer 2 disposed on the one principal surface of the support, and the functional electrode disposed on at least one principal surface of the piezoelectric layer 2 to at least partially overlap the space 9 as viewed in the first direction which is a lamination direction of the support and the piezoelectric layer 2. The functional electrode is an interdigital transducer electrode including the first busbar 5, the second busbar 6 facing the first busbar 5 in the second direction crossing the first direction, the plurality of first electrode fingers 3A with proximal ends connected to the first busbar 5 and distal ends disposed in the second direction of the first busbar, and the plurality of second electrode fingers 4A with proximal ends connected to the second busbar 6 and distal ends disposed in the second direction of the second busbar 6. At least one electrode finger of the plurality of first electrode fingers 3A and the plurality of second electrode fingers 4A has a portion with a width that linearly changes in the second direction. When the ratio of the width at the proximal end of the at least one electrode finger to the minimum width between the proximal end of the at least one electrode finger and the distal end of the at least one electrode finger is 1+σ:1−σ, σ of the at least one electrode finger is greater than or equal to about 0.01 and less than or equal to about 0.054. This can reduce the strength index of unwanted waves while reduce or prevent degradation of FOM, and thus can suppress generation of unwanted waves.

In an example embodiment, σ is greater than or equal to about 0.03, for example. This can further reduce the strength index of unwanted waves, and thus can further reduce or prevent generation of unwanted waves.

In an example embodiment, all electrode fingers of the plurality of first electrode fingers 3A and the plurality of second electrode fingers 4A include a portion with a width that linearly changes in the second direction. This can further reduce or prevent generation of unwanted waves.

In an example embodiment, for example, d/p is less than or equal to about 0.5, where d is the film thickness of the piezoelectric layer 2 and p is the center-to-center distance between adjacent first and second electrode fingers 3 and 4. This can effectively excite first-order thickness shear mode bulk waves.

In an example embodiment, the piezoelectric layer 2 includes, for example, lithium niobate or lithium tantalate. This makes it possible to provide an acoustic wave device having good resonance characteristics.

In an example embodiment, Euler angles (φ, θ, ψ) of lithium niobate or lithium tantalate forming the piezoelectric layer 2 are in the range defined by expression (1), expression (2), or expression (3) described below. This can reliably make the fractional bandwidth less than or equal to about 17%.

$$( 0 ° \pm 10 ° , 0 ° to 20 ° , any ψ ) \qquad expression ( 1 )$$

$$( 0 ° \pm 10 ° , 20 ° to 80 ° , 0 ° to 60 ° {( 1 + {( θ - 50 )}^{2} / 900 )}^{1 / 2} ) or ( 0 ° \pm 10 ° , 20 ° to 80 ° , \{ 180 ° - 60 ° {( 1 - {( θ - 50 )}^{2} / 900 )}^{1 / 2} \} to 180 ° ) \qquad expression ( 2 )$$

$$( 0 ° \pm 10 ° , \{ 180 ° - 30 ° \{ 180 ° - 30 ° {( 1 - {( ψ - 90 )}^{2} / 8100 )}^{1 / 2} \} to 180 ° , any ψ ) \qquad expression ( 3 )$$

In an example embodiment, the acoustic wave device is configured to generate thickness shear mode bulk waves. This improves the coupling coefficient and makes it possible to provide an acoustic wave device having good resonance characteristics.

In an example embodiment, for example, d/p is less than or equal to about 0.24, where d is the film thickness of the piezoelectric layer 2 and p is the center-to-center distance between adjacent first and second electrode fingers 3 and 4. This can effectively excite first-order thickness shear mode bulk waves.

In an example embodiment, when a region where adjacent first and second electrode fingers 3 and 4 overlap as viewed in the direction in which the adjacent first and second electrode fingers 3 and 4 face each other is defined as an excitation region, for example, MR≤about 1.75 (d/p)+0.075 is satisfied, where MR is the metallization ratio of the plurality of first electrode fingers 3 and the plurality of second electrode fingers 4 to the excitation region. This can effectively reduce spurious radiation.

In an example embodiment, the acoustic wave device is configured to be capable of using plate waves. This makes it possible to provide an acoustic wave device having good resonance characteristics.

### Second Example Embodiment

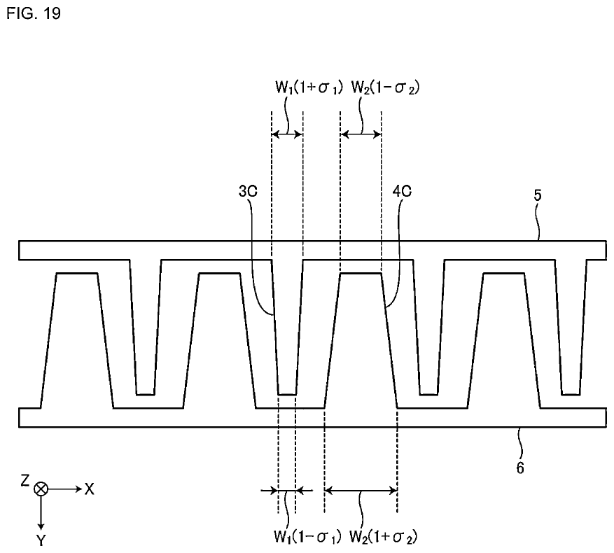

FIG. 18 is a schematic plan view illustrating an example of an electrode structure of an acoustic wave device according to a second example embodiment of the present invention. As illustrated in FIG. 18, the acoustic wave device according to the second example embodiment differs from the first example embodiment in that electrode fingers 3B and 4B include two or more portions 3Ba, 3Bb, 4Ba, and 4Bb with a width that linearly changes in the Y direction. In the example illustrated in FIG. 18, the electrode fingers 3B and 4B include the portions 3Ba and 4Ba with a width that decreases from the proximal end toward the distal end, and the portions 3Bb and 4Bb with a width that increases from the proximal end toward the distal end. The portions 3Ba, 4Ba, 3Bb, and 4Bb have, for example, an isosceles trapezoidal shape in plan view in the Z direction. That is, the electrode fingers 3B and 4B define, for example, a hexagon whose sides facing each other in the Y direction are parallel or substantially parallel and two angles between the proximal end and the distal end are greater than about 180°. In this case, the width between the proximal end and the distal end of the electrode fingers 3B and 4B is minimum between the portions 3Ba and 3Bb, and between the portions 4Ba and 4Bb, in the Y direction.

The electrode structure of the acoustic wave device according to the second example embodiment is not limited to the example illustrated in FIG. 18. For example, each electrode finger may include three or more portions with a width that linearly changes in the Y direction. For example, each electrode finger may include a first portion having a width that decreases from the proximal end toward the distal end, and a second portion having a width that decreases from the proximal end toward the distal end and tapered to a different degree from the first portion. For example, only some of the plurality of electrode fingers may include two or more portions with a width that linearly changes in the Y direction.

As described above, in the acoustic wave device according to the second example embodiment, at least one electrode finger (electrode fingers 3B and 4B) includes two or more portions 3Ba, 3Bb, 4Ba, and 4Bb with a width that linearly changes in the second direction. Generation of unwanted waves can be reduced or prevented even in this case.

### Third Example Embodiment

FIG. 19 is a schematic plan view illustrating an example of an electrode structure of an acoustic wave device according to a third example embodiment of the present invention. As illustrated in FIG. 19, the acoustic wave device according to the third example embodiment differs from the first example embodiment in that electrode fingers 3C and 4C differ in the value of σ. In the example illustrated in FIGS. 19, σ₁ and σ₂ differ when the width at the proximal end of the electrode finger 3C is W₁ (1+σ₁), the minimum width between the proximal end and the distal end of the electrode finger 3C is W₁ (1−σ₁), the width at the proximal end of the electrode finger 4C is W₂ (1+02), and the minimum width between the proximal end and the distal end of the electrode finger 4C is W₂ (1−σ₂).

The electrode structure of the acoustic wave device according to the third example embodiment is not limited to the example illustrated in FIG. 19. For example, W₁ and W₂ may be the same or substantially the same. For example, W₁ may be greater than W₂. For example, some of the plurality of electrode fingers connected to the same busbar may differ in σ.

As described above, in the acoustic wave device according to the third example embodiment, at least two electrode fingers of the plurality of first electrode fingers 3C and the plurality of second electrode fingers 4C include a portion with a width that linearly changes in the second direction, and the at least two electrode fingers differ in σ. Generation of unwanted waves can be reduced or prevented even in this case.

### Fourth Example Embodiment

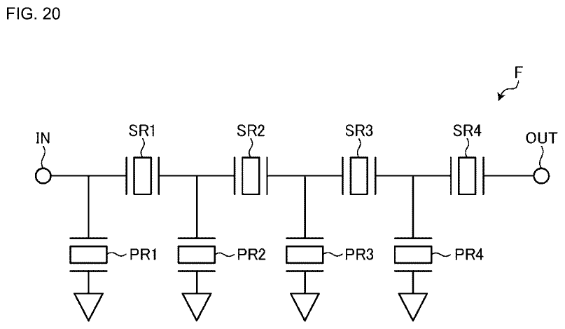

FIG. 20 is a circuit diagram illustrating an example of a filter apparatus according to a fourth example embodiment of the present invention. A filter apparatus F according to the fourth example embodiment includes the acoustic wave device according to the first example embodiment.

As illustrated in FIG. 20, the filter apparatus F is a filter that includes a plurality of resonators connected to each other. In the example illustrated in FIG. 20, the filter apparatus F is, for example, a ladder filter that includes series arm resonators SR1 to SR4 inserted in series with a signal path (first path) extending from an input terminal IN to an output terminal OUT, and parallel arm resonators PR1 to PR4 each inserted in a signal path (second path) between a node on the first path and the ground. The series arm resonators SR1 to SR4 are electrically connected at one terminal thereof to the input terminal IN and electrically connected at the other terminal thereof to the output terminal OUT. The parallel arm resonators PR1 to PR4 are electrically connected at one terminal thereof to the input terminal IN and electrically connected at the other terminal thereof to the ground. The number of resonators of the filter apparatus F illustrated in FIG. 20 is merely an example. The filter apparatus F may be a filter other than a ladder filter.

In the fourth example embodiment, at least one of the series arm resonators SR1 to SR4 and the parallel arm resonators PR1 to PR4 in the filter apparatus F is the acoustic wave device according to the first example embodiment. That is, at least one resonator of the series arm resonators SR1 to SR4 and the parallel arm resonators PR1 to PR4 is a resonator including an interdigital transducer electrode, and at least one electrode finger of the interdigital transducer electrode includes a portion with a width that linearly changes in the length direction. This can reduce or prevent generation of unwanted waves, and thus can improve filter characteristics. The filter apparatus F may include the acoustic wave device according to the second or third example embodiment, instead of the acoustic wave device according to the first example embodiment.

As described above, the filter apparatus F according to the fourth example embodiment includes a plurality of resonators (the series arm resonators SR1 to SR4 and the parallel arm resonators PR1 to PR4), and at least one resonator of the plurality of resonators is the acoustic wave device according to the first example embodiment. Since the acoustic wave device can reduce or prevent generation of unwanted waves, improved filter characteristics can be achieved.

The example embodiments described above are provided to facilitate understanding of the present invention, and are not intended to limit interpretation of the present invention. The present invention can be changed or modified without departing from the scope and spirit of the present invention, and the present invention also includes equivalents thereof.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support including a space in one principal surface thereof;
a piezoelectric layer on the one principal surface of the support; and
a functional electrode on at least one principal surface of the piezoelectric layer to at least partially overlap the space as viewed in a first direction, the first direction being a lamination direction of the support and the piezoelectric layer;
wherein
the functional electrode is an interdigital transducer electrode including a first busbar, a second busbar facing the first busbar in a second direction crossing the first direction, a plurality of first electrode fingers including proximal ends connected to the first busbar and distal ends provided in the second direction of the first busbar, and a plurality of second electrode fingers including proximal ends connected to the second busbar and distal ends provided in the second direction of the second busbar;
at least one electrode finger of the plurality of first electrode fingers and the plurality of second electrode fingers includes a portion with a width that linearly changes in the second direction; and
when a ratio of a width at the proximal end of the at least one electrode finger to a minimum width between the proximal end of the at least one electrode finger and the distal end of the at least one electrode finger is 1+σ:1−σ, σ of the at least one electrode finger is greater than or equal to about 0.01 and less than or equal to about 0.054.

2. The acoustic wave device according to claim 1, wherein the σ is greater than or equal to about 0.03.

3. The acoustic wave device according to claim 1, wherein the at least one electrode finger includes two or more portions with a width that linearly changes in the second direction.

4. The acoustic wave device according to claim 1, wherein at least two electrode fingers of the plurality of first electrode fingers and the plurality of second electrode fingers include a portion with a width that linearly changes in the second direction, and the at least two electrode fingers differ in σ.

5. The acoustic wave device according to claim 1, wherein all electrode fingers of the plurality of first electrode fingers and the plurality of second electrode fingers include a portion with a width that linearly changes in the second direction.

6. The acoustic wave device according to claim 1, wherein d/p is less than or equal to about 0.5, where d is a film thickness of the piezoelectric layer and p is a center-to-center distance between adjacent first and second electrode fingers.

7. The acoustic wave device according to claim 1, wherein the piezoelectric layer includes lithium niobate or lithium tantalate.

8. The acoustic wave device according to claim 7, wherein Euler angles (φ, θ, ψ) of the lithium niobate or the lithium tantalate of the piezoelectric layer are in a range defined by expression (1), expression (2), or expression (3):
$$( 0 ° \pm 10 ° , 0 ° to 20 ° , any ψ ) ; \qquad expression ( 1 )$$
$$( 0 ° \pm 10 ° , 20 ° to 80 ° , 0 ° to 60 ° {( 1 - {( θ - 50 )}^{2} / 900 )}^{1 / 2} ) or ( 0 ° \pm 10 ° , 20 ° to 80 ° , \{ 180 ° - 60 ° {( 1 - {( θ - 50 )}^{2} / 900 )}^{1 / 2} \} to 180 ° ) ; \qquad expression ( 2 )$$
$$and$$
$$( 0 ° \pm 10 ° , \{ 180 ° - 30 ° {( 1 - {( ψ - 90 )}^{2} / 8100 )}^{1 / 2} \} to 180 ° , any ψ ) . \qquad expression ( 3 )$$

9. The acoustic wave device according to claim 1, wherein the acoustic wave device is configured to generate thickness shear mode bulk waves.

10. The acoustic wave device according to claim 6, wherein d/p is less than or equal to about 0.24.

11. The acoustic wave device according to claim 1, wherein, when a region where adjacent first and second electrode fingers overlap as viewed in a direction in which the adjacent first and second electrode fingers face each other is defined as an excitation region, MR≤about 1.75 (d/p)+0.075 is satisfied, where MR is a metallization ratio of the plurality of first electrode fingers and the plurality of second electrode fingers to the excitation region.

12. The acoustic wave device according to claim 1, wherein the acoustic wave device is configured to generate plate waves.

13. A filter apparatus comprising:
a plurality of resonators; wherein
at least one resonator of the plurality of resonators is defined by the acoustic wave device according to claim 1.

14. The filter apparatus according to claim 13, wherein the σ is greater than or equal to about 0.03.

15. The filter apparatus according to claim 13, wherein the at least one electrode finger includes two or more portions with a width that linearly changes in the second direction.

16. The filter apparatus according to claim 13, wherein at least two electrode fingers of the plurality of first electrode fingers and the plurality of second electrode fingers include a portion with a width that linearly changes in the second direction, and the at least two electrode fingers differ in σ.

17. The filter apparatus according to claim 13, wherein all electrode fingers of the plurality of first electrode fingers and the plurality of second electrode fingers include a portion with a width that linearly changes in the second direction.

18. The filter apparatus according to claim 13, wherein d/p is less than or equal to about 0.5, where d is a film thickness of the piezoelectric layer and p is a center-to-center distance between adjacent first and second electrode fingers.

19. The filter apparatus according to claim 13, wherein the piezoelectric layer includes lithium niobate or lithium tantalate.

20. The filter apparatus according to claim 19, wherein Euler angles (φ, θ, ψ) of the lithium niobate or the lithium tantalate of the piezoelectric layer are in a range defined by expression (1), expression (2), or expression (3):
$$( 0 ° \pm 10 ° , 0 ° to 20 ° , any ψ ) ; \qquad expression ( 1 )$$
$$( 0 ° \pm 10 ° , 20 ° to 80 ° , 0 ° to 60 ° {( 1 - {( θ - 50 )}^{2} / 900 )}^{1 / 2} ) or ( 0 ° \pm 10 ° , 20 ° to 80 ° , \{ 180 ° - 60 ° {( 1 - {( θ - 50 )}^{2} / 900 )}^{1 / 2} \} to 180 ° ) ; \qquad expression ( 2 )$$
$$and$$
$$( 0 ° \pm 10 ° , \{ 180 ° - 30 ° {( 1 - {( ψ - 90 )}^{2} / 8100 )}^{1 / 2} \} to 180 ° , any ψ ) . \qquad expression ( 3 )$$
